(19) United States
(12) Patent Application Publication
(10) Pub. No.: US 2018/0105927 A1
(43) Pub. Date: Apr. 19, 2018

(54) METHOD FOR PREPARING HIGH-HARDNESS ANTI-BACTERIAL PVD FILM

(71) Applicants: Fook Chi MAK, Shenzhen City (CN); Sai Chi MAK, Shenzhen City (CN)

(72) Inventors: Fook Chi MAK, Shenzhen City (CN); Sai Chi MAK, Shenzhen City (CN)

(21) Appl. No.: 15/351,155

(22) Filed: Nov. 14, 2016

(30) Foreign Application Priority Data
Oct. 18, 2016 (CN) 201610904863.0

(51) Int. Cl. C23C 14/34; C23C 14/02; C23C 14/14; C23C 14/16; C22C 27/04

(52) U.S. Cl. CPC C23C 14/3464; C23C 14/021; C22C 27/04; C23C 14/165; C23C 14/3435; C23C 14/14

(57) ABSTRACT

A method for preparing a high-hardness anti-bacterial PVD film by deposition of a first anti-bacterial film layer on a workpiece with W—Ti alloy material, wherein W has high hardness and an extremely strong anti-bacterial property, and the combination of Ti and W can facilitate adhesion during the deposition of the anti-bacterial film, thus enhancing the PVD film effect; a second anti-bacterial film layer deposited on the W—Ti anti-bacterial film is W—Ti—Ag, and the addition of nano-silver in the second anti-bacterial film layer can enhance the anti-bacterial effect, and the high hardness of W can protect nano-silver; because of the anti-bacterial property of W itself, only a small amount of nano-silver needs to be added in the outermost layer, and as the price of W is lower than nano-silver in the market, the technical solution can lower the production cost of anti-bacterial film.

### BACKGROUND OF THE INVENTION

### Technical Field

The present invention relates to the technical field of PVD anti-bacterial films, and more especially, to a method for preparing a high-hardness anti-bacterial PVD film.

### Description of Related Art

Physical Vapor Deposition (PVD) refers to the process of achieving material transfer, that is, transferring atoms or molecules from a source to the substrate surface via physical processes. Different metals can be selected for evaporation and ionization into an electronic state in the practice of PVD, and then a bias voltage is used to lead ions onto a workpiece for deposition to form a thin film. Before deposition onto a workpiece, ions can also combine with other ions via reaction to form composite films which vary in aspects like hardness, brightness, friction coefficient and color, thus meeting the requirements for function or appearance.

Nowadays, influenced by environmental pollution and other factors, many articles people contact in life always have a large number of bacteria which become sources of bacterial contamination and disease spread. Therefore, it has a very important practical significance to develop coating products with an anti-bacterial characteristic for improvement of people's living conditions and protection of people's health. Nano-silver has been proved to have strong inhibitory and killing properties on dozens of pathogenic microorganisms that are common in life without generating drug tolerance, so nano-silver is now widely used in life.

In anti-bacterial application of Nano-silver in the prior art, nano-silver was usually mixed with other materials to protect a workpiece surface by coating, or a thin film containing nano-silver was directly plated on a workpiece surface. However, due to uneven distribution of nano-silver or inferior wear resistance of coatings which cannot ensure sustained anti-bacterial action for a long time, and the high price of nano-silver, these methods are poor in economical and practical consideration. According to the prior art, tungsten also has a strong anti-bacterial capacity and a great advantage in wear resistance for its extremely high hardness, but its anti-bacterial capacity is poorer than that of nano-silver, so now it is expected to integrate the advantages of tungsten and nano-silver to prepare an economical PVD film with a good wear-resistant and anti-bacterial effect.

### BRIEF SUMMARY OF THE INVENTION

The objective of the present invention is to provide a method for preparing a high-hardness anti-bacterial PVD film to solve the problems of high cost and poor wear resistance of the anti-bacterial PVD films in the prior art.

A method for preparing a high-hardness anti-bacterial PVD film, comprising the following steps:

1) workpiece pretreatment: wash away oil on a workpiece surface and remove the oxide film on the workpiece surface, and then put the workpiece in a vacuum chamber;

2) workpiece cleaning: vacuumize the vacuum chamber, heat it up to 120˜150° C., fill it with Ar and activate a Ti arc-target for ion cleaning of the workpiece;

3) base film: inactivate the Ti arc-target and activate a Ti sputtering target, continue to fill it with Ar and apply a bias voltage of −70˜−90V for deposition of a Ti base film on the workpiece surface;

4) first anti-bacterial film layer: inactivate the Ti sputtering target and activate a W—Ti alloy arc-target, fill it with Ar and apply a bias voltage of −70˜−90V for deposition of a first anti-bacterial film layer on the Ti film;

5) second anti-bacterial film layer: continue to activate the W—Ti alloy arc-target and meanwhile activate a nano-silver sputtering target, maintain it for 3˜5 min for deposition of a second anti-bacterial film layer.

In one embodiment, the method also comprises the process of inactivating the W—Ti alloy arc-target, the nano-silver sputtering target and all power sources after the deposition of the second anti-bacterial film layer has been completed, and then removing workpiece after the pressure in the vacuum chamber gradually rises and the temperature reduces to 65˜75° C.

In one embodiment, the workpiece is subject to ion cleaning in a vacuum chamber under a bias voltage of −700˜−900V during the cleaning of the workpiece.

In one embodiment, during the deposition of the first anti-bacterial film layer, the pressure in the vacuum chamber is 4.0×10−3˜6.0×10−3 Pa.

In one embodiment, the W—Ti alloy arc-target can be replaced by a W—Ti sputtering target during the deposition of the first anti-bacterial film layer by means of sputtering for forming a film.

In one embodiment, the W:Ti mass fraction of the W—Ti alloy is 1:1˜9:1.

In one embodiment, the mass content of nano-silver in the second anti-bacterial film layer is 2%˜5%.

In one embodiment, one of N2, O2 or C2H2 is filled during the deposition of the first anti-bacterial film layer.

The disclosure above shows a method for preparing a high-hardness anti-bacterial PVD film by deposition of a first anti-bacterial film layer on a workpiece with W—Ti alloy material, wherein W has high hardness and an extremely strong anti-bacterial property, and the combination of Ti and W can facilitate adhesion during the deposition of the anti-bacterial film, thus enhancing the PVD film effect; a second anti-bacterial film layer deposited on the W—Ti anti-bacterial film is W—Ti—Ag, and the addition of nano-silver in the second anti-bacterial film layer can enhance the anti-bacterial effect of the anti-bacterial film, and the high hardness of W can protect the nano-silver; because of the anti-bacterial property of W itself, only a small amount of nano-silver needs to be added in the outermost layer of the anti-bacterial film, and because the price of W is lower than nano-silver in the market, the technical solution above can reduce the production cost of anti-bacterial film.

### BRIEF DESCRIPTION OF THE SEVERAL VIEWS OF THE DRAWINGS

FIG. 1 is a structural diagram of the high-hardness anti-bacterial PVD film of the present invention.

### DETAILED DESCRIPTION OF THE INVENTION

The present invention is further detailed in combination with the drawings and embodiments as follows.

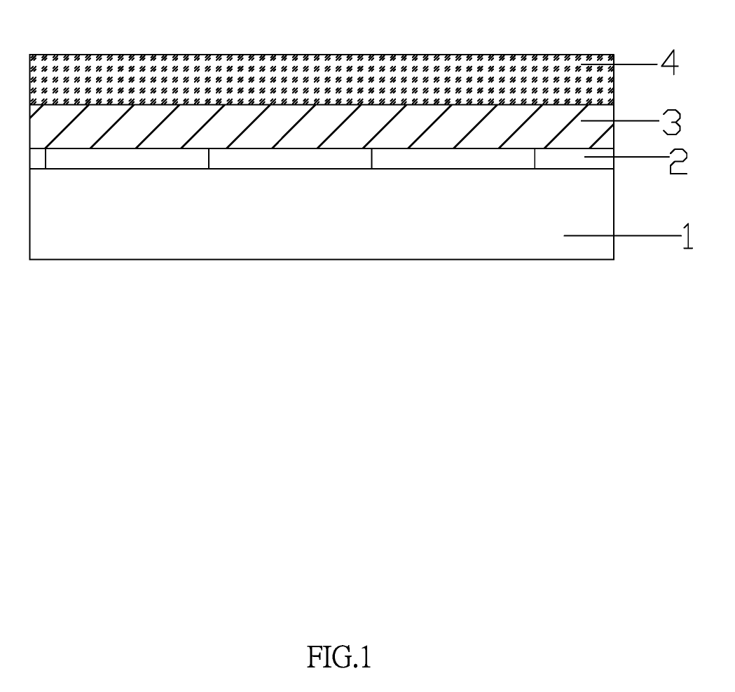

As shown in FIG. 1, a method for preparing a high-hardness anti-bacterial PVD film is disclosed, comprising the following steps:

1) workpiece 1 pretreatment: wash away oil on a workpiece 1 surface and remove the oxide film on the workpiece 1 surface, and then put the workpiece 1 in a vacuum chamber; 2) workpiece 1 cleaning: vacuumize the vacuum chamber, heat it up to 120˜150° C., fill it with Ar and activate a Ti arc-target for ion cleaning of the workpiece 1; 3) base film 2: inactivate the Ti arc-target and activate a Ti sputtering target, continue to fill it with Ar and apply a bias voltage of −70˜−90V for deposition of a Ti base film 2 on the workpiece 1 surface; 4) first anti-bacterial film layer 3: inactivate the Ti sputtering target and activate a W—Ti alloy arc-target, fill it with Ar and apply a bias voltage of −70˜−90V for deposition of a first anti-bacterial film layer 3 on the Ti film; 5) second anti-bacterial film layer 4: continue to activate the W—Ti alloy arc-target and meanwhile activate a nano-silver sputtering target, maintain it for 3˜5 min for deposition of a second anti-bacterial film layer 4. To enhance adhesion of the film deposited on the workpiece 1 in the vacuum chamber, it is required to pretreat and clean the workpiece 1 surface, wherein oil on the workpiece 1 surface is usually cleaned with a detergent and oxide film is removed by ultrasonic means. The main objective of ion-cleaning the workpiece 1 surface in the vacuum chamber with the Ti arc-target is to enhance the activate on the workpiece 1 surface, thus making the adhesion of the film strong and uniform later. The Ti base film 2 is deposited on the workpiece 1 surface prior to the deposition of the first anti-bacterial film layer 3, since W does not have strong adhesion in the PVD filming process; to increase the effect of the PVD film and keep W and Ti combined, the Ti base film 2 is plated prior to the first anti-bacterial film layer. The second anti-bacterial film layer 4 is a W—Ti—Ag film.

Molecular formulas in the patent application are all expressed by chemical formulas, wherein Ar refers to argon, W refers to tungsten (metal), Ti refers to titanium (metal) and Ag refers to nano-silver.

The target materials used in the patent application are formed by hydraulic press of nano-metal powder. Therefore, the W—Ti alloy target is formed by hydraulic press of W powder and Ti powder mixed uniformly at a certain ratio and the silver target is formed by hydraulic press of silver powder.

In one embodiment, the method also comprises the process of inactivating the W—Ti alloy arc-target, the silver sputtering target and all power sources after the deposition of the second anti-bacterial film layer 4 has been completed, and then removing workpiece 1 after the pressure in the vacuum chamber gradually rises and the temperature reduces to 65˜75° C.

In one embodiment, the workpiece 1 is subject to ion cleaning in a vacuum chamber under a bias voltage of −700˜−900V during the cleaning of the workpiece 1.

In one embodiment, during the deposition of the first anti-bacterial film layer 3, the pressure in the vacuum chamber is 4.0×10−3˜6.0×10−3 Pa.

In one embodiment, the W—Ti alloy arc-target can be replaced by a W—Ti sputtering target during the deposition of the first anti-bacterial film layer 3 by means of sputtering for forming a film. A variety of PVD methods are feasible, wherein an arc target may be replaced by a sputtering target in the deposition process of first anti-bacterial film layer 3, that is, arc plating may be replaced by sputtering plating, and both can bring a good filming effect.

In one embodiment, the W:Ti mass fraction of the W—Ti alloy is 1:1˜9:1. Ti is mainly used for enhancing the filming effect while W is mainly for anti-bacteria during the plating of the anti-bacterial film, and because W has high hardness and wear resistance, the ratio of W in W—Ti alloy shall be higher than Ti in the process.

In one embodiment, the mass content of nano-silver in the second anti-bacterial film layer 4 is 2%˜5%. To enhance the anti-bacterial effect of the anti-bacterial film, a small amount of nano-silver is added to the second anti-bacterial film layer 4, and the nano-silver can be protected by W—Ti, thus prolonging the service life.

In one embodiment, one of N2, O2 or C2H2 is filled during the deposition of the first anti-bacterial film layer 3. The colors of films from filling with different gases during the PVD filming vary eventually, wherein using N2 as an activating gas makes a film formed in golden yellow, using O2 makes a film in blue and using C2H2 makes a film in black.

Embodiments are provided herein for further explanation as follows:

### Embodiment 1

1) workpiece 1 pretreatment: wash away oil on a workpiece 1 surface and remove the oxide film on the workpiece 1 surface, and then put the workpiece 1 in a vacuum chamber; 2) workpiece 1 cleaning: vacuumize the vacuum chamber, heat it up to 120° C., apply a bias voltage of −900V, fill it with Ar and activate a Ti arc-target for ion cleaning of the workpiece 1; 3) base film 2: inactivate the Ti arc-target and activate a Ti sputtering target, continue to fill it with Ar and apply a bias voltage of −90V for deposition of a Ti base film 2 on the workpiece 1 surface; 4) first anti-bacterial film layer 3: inactivate the Ti sputtering target and activate a W—Ti alloy arc-target, fill it with Ar and apply a bias voltage of −90V with the pressure in the vacuum chamber being 4.0×10−3 Pa for deposition of a first anti-bacterial film layer 3 on the Ti film, and the W:Ti mass fraction of the W—Ti alloy is 1:1; 5) second anti-bacterial film layer 4; continue to activate the W—Ti alloy arc-target and meanwhile activate a silver sputtering target, maintain it for 3 min for deposition of a second anti-bacterial film layer 4, and the mass content of nano-silver is 2%; 6) inactivate the W—Ti alloy arc-target, the silver sputtering target and all power sources after the deposition of the second anti-bacterial film layer 4 has been completed, and then take out of the workpiece 1 after the pressure in the vacuum furnace gradually rises and the temperature reduces to 75° C.

### Embodiment 2

1) workpiece 1 pretreatment: wash away oil on a workpiece 1 surface and remove the oxide film on the workpiece 1 surface, and then put the workpiece 1 in a vacuum chamber; 2) workpiece 1 cleaning: vacuumize the vacuum chamber, heat it up to 150° C., apply a bias voltage of −700V, fill it with Ar and activate a Ti arc-target for ion cleaning of the workpiece 1; 3) base film 2: inactivate the Ti arc-target and activate a Ti sputtering target, continue to fill it with Ar and apply a bias voltage of −70V for deposition of a Ti base film 2 on the workpiece 1 surface; 4) first anti-bacterial film layer 3: inactivate the Ti sputtering target and activate a W—Ti alloy arc-target, fill it with Ar and N2 as well, and apply a bias voltage of −70V with the pressure in the vacuum chamber being 6.0×10−3 Pa for deposition of a first anti-bacterial film layer 3 in golden yellow on the Ti film, and the W:Ti mass fraction of the W—Ti alloy is 9:1; 5) second anti-bacterial film layer 4: continue to activate the W—Ti alloy arc-target and meanwhile activate a silver sputtering target, maintain it for 5 min for deposition of a second anti-bacterial film layer 4, and the mass content of nano-silver is 5%; 6) inactivate the W—Ti alloy arc-target, the silver sputtering target and all power sources after the deposition of the second anti-bacterial film layer 4 has been completed, and then take out of the workpiece 1 after the pressure in the vacuum chamber gradually rises and the temperature reduces to 65° C.

### Embodiment 3

1) workpiece 1 pretreatment: wash away oil on a workpiece 1 surface and remove the oxide film on the workpiece 1 surface, and then put the workpiece 1 in a vacuum chamber; 2) workpiece 1 cleaning: vacuumize the vacuum chamber, heat it up to 135° C., apply a bias voltage of −800V, fill it with Ar and activate a Ti arc-target for ion cleaning of the workpiece 1; 3) base film 2: inactivate the Ti arc-target and activate a Ti sputtering target, continue to fill it with Ar and apply a bias voltage of −80V for deposition of a Ti base film 2 on the workpiece 1 surface; 4) first anti-bacterial film layer 3: inactivate the Ti sputtering target and activate a W—Ti alloy arc-target, fill it with Ar and O2 as well, and apply a bias voltage of −80V with the pressure in the vacuum furnace being 5.0×10−3 Pa for deposition of a first anti-bacterial film layer 3 in blue on the Ti film, and the W:Ti mass fraction of the W—Ti alloy is 5:1; 5) second anti-bacterial film layer 4: continue to activate the W—Ti alloy arc-target and meanwhile activate a nano-silver sputtering target, maintain it for 4 min for deposition of a second anti-bacterial film layer 4, and the mass content of nano-silver is 3%; 6) inactivate the W—Ti alloy arc-target, the nano-silver sputtering target and all power sources after the deposition of the second anti-bacterial film layer 4 has been completed, and then take out of the workpiece 1 after the pressure in the vacuum chamber gradually rises and the temperature reduces to 70° C.

### Embodiment 4

1) workpiece 1 pretreatment: wash away oil on a workpiece 1 surface and remove the oxide film on the workpiece 1 surface, and then put the workpiece 1 in a vacuum chamber; 2) workpiece 1 cleaning: vacuumize the vacuum chamber, heat it up to 140° C., apply a bias voltage of −850V, fill it with Ar and activate a Ti arc-target for ion cleaning of the workpiece 1; 3) base film 2: inactivate the Ti arc-target and activate a Ti sputtering target, continue to fill it with Ar and apply a bias voltage of −75V for deposition of a Ti base film 2 on the workpiece 1 surface; 4) first anti-bacterial film layer 3: inactivate the Ti sputtering target and activate a W—Ti alloy arc-target, fill it with Ar and C2H2 as well, and apply a bias voltage of −85V with the pressure in the vacuum furnace being 4.0×10−3 Pa for deposition of a first anti-bacterial film layer 3 in black on the Ti film, and the W:Ti mass fraction of the W—Ti alloy is 7:1; 5) second anti-bacterial film layer 4: continue to activate the W—Ti alloy arc-target and meanwhile activate a silver sputtering target, maintain it for 3 min for deposition of a second anti-bacterial film layer 4, and the mass content of nano-silver is 4%; 6) inactivate the W—Ti alloy arc-target, the nano-silver sputtering target and all power sources after the deposition of the second anti-bacterial film layer 4 has been completed, and then take out of the workpiece 1 after the pressure in the vacuum chamber gradually rises and the temperature reduces to 72° C.

### Embodiment 5

1) workpiece 1 pretreatment: wash away oil on a workpiece 1 surface and remove the oxide film on the workpiece 1 surface, and then put the workpiece 1 in a vacuum chamber; 2) workpiece 1 cleaning: vacuumize the vacuum chamber, heat it up to 130° C., apply a bias voltage of −750V, fill it with Ar and activate a Ti arc-target for ion cleaning of the workpiece 1; 3) base film 2: inactivate the Ti arc-target and activate a Ti sputtering target, continue to fill it with Ar and apply a bias voltage of −85V for deposition of a Ti base film 2 on the workpiece 1 surface; 4) first anti-bacterial film layer 3: inactivate the Ti sputtering target and activate a W—Ti alloy arc-target, fill it with Ar and apply a bias voltage of −80V with the pressure in the vacuum chamber being 6.0×10−3 Pa for deposition of a first anti-bacterial film layer 3 on the Ti film, and the W:Ti mass fraction of the W—Ti alloy is 3:1; 5) second anti-bacterial film layer 4: continue to activate the W—Ti alloy arc-target and meanwhile activate a nano-silver sputtering target, maintain it for 5 min for deposition of a second anti-bacterial film layer 4, and the mass content of nano-silver is 5%; 6) inactivate the W—Ti alloy arc-target, the silver sputtering target and all power sources after the deposition of the second anti-bacterial film layer 4 has been completed, and then take out of the workpiece 1 after the pressure in the vacuum chamber gradually rises and the temperature reduces to 75° C.

The above-mentioned embodiments are intended to describe the present invention, but not to limit the structural characteristics of the present invention. Any modifications and polishing made by those skilled in the art shall be included in the patent scope of the present invention.

What is claimed is:

1. A method for preparing a high-hardness anti-bacterial PVD film, characterized in that it comprises the following steps:
1) workpiece pretreatment: wash away oil on a workpiece surface and remove the oxide film on the workpiece surface, and then put the workpiece in a vacuum chamber;
2) workpiece cleaning: vacuumize the vacuum chamber, heat it up to 120˜150° C., fill it with Ar and activate a Ti arc-target for ion cleaning of the workpiece;
3) base film: inactivate the Ti arc-target and activate a Ti sputtering target, continue to fill it with Ar and apply a bias voltage of −70˜−90V for deposition of a Ti base film on the workpiece surface;
4) first anti-bacterial film layer: inactivate the Ti sputtering target and activate a W—Ti alloy arc-target, fill it with Ar and apply a bias voltage of −70˜−90V for deposition of a first anti-bacterial film layer on the Ti film;
5) second anti-bacterial film layer: continue to activate the W—Ti alloy arc-target and meanwhile activate a silver sputtering target, maintain it for 3˜5 min for deposition of a second anti-bacterial film layer.

2. The method for preparing a high-hardness anti-bacterial PVD film as claimed in claim 1, characterized in that, it also comprises the process of inactivating the W—Ti alloy arc-target, the silver sputtering target and all power sources after the deposition of the second anti-bacterial film layer has been completed, and then removing workpiece after the pressure in the vacuum chamber gradually rises and the temperature reduces to 65˜75° C.

3. The method for preparing a high-hardness anti-bacterial PVD film as claimed in claim 1, characterized in that the workpiece is subject to ion cleaning in a vacuum chamber under a bias voltage of −700˜−900V during the cleaning of the workpiece.

4. The method for preparing a high-hardness anti-bacterial PVD film as claimed in claim 1, characterized in that, during the deposition of the first anti-bacterial film layer, the pressure in the vacuum furnace is 4.0×10−3˜6.0×10−3 Pa.

5. The method for preparing a high-hardness anti-bacterial PVD film as claimed in claim 1, characterized in that the W—Ti alloy arc-target can be replaced by a W—Ti sputtering target during the deposition of the first anti-bacterial film layer by means of sputtering for forming a film.

6. The method for preparing a high-hardness anti-bacterial PVD film as claimed in claim 1, characterized in that the W:Ti mass fraction of the W—Ti alloy is 1:1˜9:1.

7. The method for preparing a high-hardness anti-bacterial PVD film as claimed in claim 2, characterized in that the W:Ti mass fraction of the W—Ti alloy is 1:1˜9:1.

8. The method for preparing a high-hardness anti-bacterial PVD film as claimed in claim 3, characterized in that the W:Ti mass fraction of the W—Ti alloy is 1:1˜9:1.

9. The method for preparing a high-hardness anti-bacterial PVD film as claimed in claim 4, characterized in that the W:Ti mass fraction of the W—Ti alloy is 1:1˜9:1.

10. The method for preparing a high-hardness anti-bacterial PVD film as claimed in claim 5, characterized in that the W:Ti mass fraction of the W—Ti alloy is 1:1˜9:1.

11. The method for preparing a high-hardness anti-bacterial PVD film as claimed in claim 1, characterized in that the mass content of nano-silver in the second anti-bacterial film layer is 2%˜5%.

12. The method for preparing a high-hardness anti-bacterial PVD film as claimed in claim 2, characterized in that the mass content of nano-silver in the second anti-bacterial film layer is 2%˜5%.

13. The method for preparing a high-hardness anti-bacterial PVD film as claimed in claim 3, characterized in that the mass content of nano-silver in the second anti-bacterial film layer is 2%˜5%.

14. The method for preparing a high-hardness anti-bacterial PVD film as claimed in claim 4, characterized in that the mass content of nano-silver in the second anti-bacterial film layer is 2%˜5%.

15. The method for preparing a high-hardness anti-bacterial PVD film as claimed in claim 5, characterized in that the mass content of nano-silver in the second anti-bacterial film layer is 2%˜5%.

16. The method for preparing a high-hardness anti-bacterial PVD film as claimed in claim 1 characterized in that one of N2, O2 or C2H2 is filled during the deposition of the first anti-bacterial film layer.

17. The method for preparing a high-hardness anti-bacterial PVD film as claimed in claim 2 characterized in that one of N2, O2 or C2H2 is filled during the deposition of the first anti-bacterial film layer.

18. The method for preparing a high-hardness anti-bacterial PVD film as claimed in claim 3 characterized in that one of N2, O2 or C2H2 is filled during the deposition of the first anti-bacterial film layer.

19. The method for preparing a high-hardness anti-bacterial PVD film as claimed in claim 4 characterized in that one of N2, O2 or C2H2 is filled during the deposition of the first anti-bacterial film layer.

20. The method for preparing a high-hardness anti-bacterial PVD film as claimed in claim 5 characterized in that one of N2, O2 or C2H2 is filled during the deposition of the first anti-bacterial film layer.
